(19) United States
(12) Patent Application Publication
(10) Pub. No.: US 2021/0157238 A1
(43) Pub. Date: May 27, 2021

(54) Methods and Systems for Producing Three-Dimensional Electronic Products

(71) Applicant: Orbotech Ltd., Yavne (IL)

(72) Inventors: Gil Bernstein Toker, Yavne (IL); Sharona Cohen, Yavne (IL); Zvi Kotler, Yavne (IL)

(21) Appl. No.: 17/100,752

(22) Filed: Nov. 20, 2020

Related U.S. Application Data
(60) Provisional application No. 62/940,275, filed on Nov. 26, 2019.

(51) Int. Cl. G03F 7/16; G03F 7/004; G03F 7/033

(52) U.S. Cl. CPC G03F 7/164; G03F 7/033; G03F 7/0047

(57) ABSTRACT

A method for manufacturing, the method includes coupling a sample to a mount, and immersing at least part of the sample in a photosensitive liquid having an upper surface defining an interface between the photosensitive liquid and a surrounding environment. At least a polymer layer that is coupled to at least a section of the sample is formed by: setting a thickness of the polymer layer by controlling a position of the sample relative to the upper surface, and illuminating at least the upper surface so as to polymerize the photosensitive liquid to form the polymer layer.

### FIELD OF THE INVENTION

The present invention relates generally to production of electronic products, and particularly to methods and systems for producing three-dimensional products using techniques that combine stereolithography and other processes.

### BACKGROUND OF THE INVENTION

Various processes, such as stereolithography, have been developed for producing three-dimensional (3D) products.

For example, U.S. Pat. No. 5,705,117 describes a stereolithography process for developing a prototype part in which inserts of a non-photopolymer material are included within the resulting part so as to develop a functioning prototype part. A non-photopolymer insert is manually positioned on one section of the developing part each time a section is formed.

U.S. Pat. No. 7,373,214 describes a system that prints three dimensional products, the system including at least one object incorporation device that incorporates non-printed objects into partially completed product, the non-printed objects not being printed by the system.

### SUMMARY OF THE INVENTION

An embodiment of the present invention that is described herein provides a method for manufacturing, the method includes coupling a sample to a mount, and immersing at least part of the sample in a photosensitive liquid having an upper surface defining an interface between the photosensitive liquid and a surrounding environment. At least a polymer layer that is coupled to at least a section of the sample is formed by: setting a thickness of the polymer layer by controlling a position of the sample relative to the upper surface, and illuminating at least the upper surface so as to polymerize the photosensitive liquid to form the polymer layer.

In some embodiments, illuminating at least the upper surface includes using two or more wavelengths or two or more ranges of wavelengths. In other embodiments, forming the polymer layer includes controlling a viscosity of the photosensitive liquid for coupling the polymer layer to the at least section of the sample. In yet other embodiments, controlling the viscosity includes controlling at least one of a temperature and a chemical composition of the photosensitive liquid.

In an embodiment, setting the thickness of the polymer layer includes wiping at least part of the photosensitive liquid from the upper surface. In another embodiment, the method includes directing droplets of molten material toward at least a solid surface of the sample in accordance with a predefined pattern so that the droplets harden on the solid surface to print a structure of one or more layers on the solid surface. In yet another embodiment, the solid surface includes at least part of the polymer layer.

In some embodiment, the method includes removing at least part of the polymer layer for exposing at least a given surface of the structure to the surrounding environment. In other embodiments, the method includes forming an electrical contact on the given surface by directing additional droplets toward a predefined position on the given surface in accordance with an additional predefined pattern, so that the additional droplets harden on the given surface to print the electrical contact at the predefined position. In yet other embodiments, the structure includes a three-dimensional (3D) structure.

In an embodiment, the method includes forming a cavity in the polymer layer and directing the droplets toward the cavity to print at least part of the structure in the cavity. In another embodiment, forming at least the polymer layer includes fixating the structure to the solid surface. In yet another embodiment, forming at least the polymer layer includes covering the structure with at least the polymer layer.

In some embodiments, the method includes coupling to the sample an electronic device having at least a contact pad, and forming at least the polymer layer on at least a section of the electronic device. In other embodiments, the method includes forming an electrical contact on a pad surface of at least the contact pad by directing additional droplets toward the pad surface in accordance with a predefined pattern so that the additional droplets harden on the pad surface. In yet other embodiments, the electrical contact includes a pillar coupled to the pad surface for conducting electrical signals to or from the electronic device.

In an embodiment, coupling the electronic device includes immersing at least part of the electronic device in the photosensitive liquid, and the method includes heating the sample for polymerizing at least part of the photosensitive liquid to form at least part of the polymer layer. In another embodiment, the method includes forming a cavity at a selected position in the polymer layer and filling the cavity with a given liquid. In yet another embodiment, forming the cavity includes (a) illuminating the photosensitive liquid at one or more positions surrounding the selected position such that the photosensitive liquid is not polymerized at the selected position, and (b) removing the photosensitive liquid from the selected position to form the cavity.

In some embodiments, removing the photosensitive liquid includes one of (a) pumping the photosensitive liquid out of the selected position, and (b) inserting a solid element into the cavity. In other embodiments, filling the cavity includes dispensing the given liquid into the cavity. In yet other embodiments, the given liquid differs from the photosensitive liquid by at least one property selected from a list of properties consisting of: (a) a mechanical property, (b) a thermal property, (c) an electrical property, and (d) a chemical property.

In some embodiments, the given liquid includes a given photosensitive liquid, and the method includes illuminating a selected pattern of the given photosensitive liquid so as to polymerize the selected pattern of the given photosensitive liquid to form the selected pattern having a given polymer layer within the cavity. In other embodiments, the method includes (a) forming an electrical component above or below the polymer layer, (b) patterning a cavity in the polymer layer, (c) filling the cavity with a substance that differs from the polymer layer, and (d) disposing a flexible member at least on the substance. In yet another embodiment, the electrical component includes a resistor, and wherein the substance has a first coefficient of thermal expansion (CTE) larger than a second CTE of the polymer layer.

In an embodiment, the electrical component includes a capacitor, and the substance has a first mechanical rigidness smaller than a second mechanical rigidness of the polymer layer. In another embodiment, the flexible member includes polyimide or silicone. In yet another embodiment, the photosensitive liquid includes one or more substances selected from a list consisting of: (a) chemical moieties photopolymerizable to form epoxy or silicone polymers, (b) polyimide, (c) polyurethanes, (d) polydicyclopentadiene, (e) photosensitive polymerizable silanes, and photopolymerizable moietie.

In some embodiments, illuminating at least the upper surface includes illuminating the photosensitive liquid using ultraviolet (UV) radiation. In other embodiments, the method includes preparing a given surface of the polymer layer before applying a layer or coupling a device to the given surface. In yet other embodiments, applying the layer includes directing droplets of molten material toward the given surface of the polymer layer in accordance with a predefined pattern so that the droplets harden on the given surface to print the layer on the given surface.

In an embodiment, preparing the given surface includes applying an adhesion layer to the given surface before applying the layer. In another embodiment, preparing the given surface includes patterning a cavity in the given layer and applying the layer to at least part of the cavity. In yet another embodiment, preparing the given surface includes roughening at least a section of the given surface using laser ablation.

In some embodiments, preparing the given surface includes applying micron-scale particles to at least a section of the given surface. In other embodiments, applying the micron-scale particles includes dispensing or jetting a diluted solution including the micron-scale particles immersed in a volatile solvent. In yet other embodiments, the method includes forming a first three-dimensional (3D) structure by directing first droplets of molten material toward at least a solid surface of the sample in accordance with a predefined pattern, so that the first droplets harden on the solid surface to print the first 3D structure on the solid surface. The first 3D structure includes a first end having a lower surface facing the solid surface and a second end having an upper surface opposite to the lower surface, and the method includes forming, on the upper surface, a second 3D structure by directing second droplets of molten material toward the upper surface, so that the second droplets harden on the upper surface to print the second 3D structure on the upper surface of the first 3D structure. Forming at least the polymer layer includes: (i) forming a first polymer layer for fixating a position of the first 3D structure on the solid surface, and (ii) forming a second polymer layer for fixating the position of the second 3D structure on the upper surface of the first 3D structure.

In an embodiment, at least one of the first and second 3D structures includes a pillar. In another embodiment, setting the thickness includes setting a given thickness, such that illuminating the upper surface includes polymerizing all the photosensitive liquid within the given thickness. In yet another embodiment, setting the thickness includes setting at least a first thickness of the first polymer layer by wiping at least part of the photosensitive liquid from a first upper surface of the photosensitive liquid.

There is additionally provided, in accordance with an embodiment of the present invention, a system for manufacturing, the system includes a photosensitive liquid, a mount, an optical assembly and a processor. The photosensitive liquid is contained in a vat and having an upper surface defining an interface between the photosensitive liquid and a surrounding environment. The mount has a sample coupled thereto and configured to immerse at least part of the sample in the photosensitive liquid by moving the sample relative to the upper surface. The optical assembly is configured to illuminate at least the upper surface so as to polymerize the photosensitive liquid to form a polymer layer. The processor is configured to set a thickness of the polymer layer by controlling a position of the sample relative to the upper surface.

There is further provided, in accordance with an embodiment of the present invention, a method for manufacturing, the method includes ejecting droplets of molten material toward a substrate in a predefined pattern so that the droplets harden on the substrate to print a three-dimensional (3D) structure on the substrate. The substrate is immersed into a photosensitive liquid, with the 3D structure thereon. The photosensitive liquid is irradiated so as to polymerize the photosensitive liquid to form one or more polymer layers that contain at least part of the 3D structure.

In some embodiments, the droplets include a molten metal. In other embodiments, the method includes placing an electronic device on the substrate, and ejecting the droplets includes making a conductive connection to the electronic device. In yet other embodiments, making the conductive connection includes printing a pillar, which extends through one or more of the polymer layers formed by polymerizing the photosensitive liquid.

In an embodiment, ejecting the droplets includes directing a laser beam to impinge on a donor film so that the droplets are ejected by laser-induced forward transfer (LIFT). In another embodiment, irradiating the photosensitive liquid includes applying patterned radiation to the photosensitive liquid so as to build up multiple polymer layers in a process of stereolithography. In yet another embodiment, ejecting the droplets includes printing the 3D structure on a first stereolithographic layer, which serves as the substrate for the 3D structure, and applying the patterned radiation includes forming at least a second stereolithographic layer over the first stereolithographic layer.

The present invention will be more fully understood from the following detailed description of the embodiments thereof, taken together with the drawings in which:

### BRIEF DESCRIPTION OF THE DRAWINGS

FIG. 1 is a schematic side view of a system for manufacturing electronic devices, in accordance with an embodiment of the present invention; and

FIGS. 2-9 are diagrams that schematically illustrate methods and process sequences for producing and embedding electronic or optoelectronic devices in electronic products, in accordance with several embodiments of the present invention.

### DETAILED DESCRIPTION OF EMBODIMENTS

### Overview

Embodiments of the present invention that are described hereinbelow provide methods and systems for producing three-dimensional (3D) electronic products by embedding and interconnecting multiple devices and components of various types in a polymeric matrix.

In some embodiments, the polymeric matrix is formed by coupling a sample to a movable stage and immersing the sample in a vat containing a photosensitive liquid having an upper surface. The stage moves the sample relative to the upper surface of the photosensitive liquid so as to obtain a desired thickness of a polymer layer of the matrix. In addition, a light source of a stereolithography illumination assembly (SLI) illuminates at least the upper surface so as to polymerize the photosensitive liquid to form the polymer layer, also referred to herein as a photopolymerized layer. Note that the SLI is configured to form a pattern in the polymer layer, or to cover the entire surface of the sample with the polymer layer.

In some embodiments, a system for producing 3D electronic products comprises a pick and place (PP) subsystem, which is configured to position first and second devices at respective first and second positions of the matrix. The shapes and dimensions of the devices may be the same or different from one another. In some embodiments, the PP may immerse at least part of the first device in the photosensitive liquid, and the SLI may polymerize the photosensitive liquid surrounding the first device so as to fixate the first device in the polymeric matrix. In other embodiments, the system is configured to produce a cavity in the polymeric matrix and the PP may position the second device in the cavity. Note that by controlling the thickness of the photosensitive liquid and the dimensions of the cavity, the system is configured to position the first and second devices at any desired position in the polymeric matrix.

In some embodiments, the system comprises a laser direct writing subsystem (LDW), which is configured to print on the photopolymerized layers, electrical traces for interconnecting the first and second devices, and/or for connecting any of the first and second devices with any other entity electrically coupled to or contained within the sample. The LDW is configured to print the electrical traces by ejecting molten metal droplets toward the sample in accordance with a predefined pattern so that the droplets harden on the substrate to form the electrical traces.

In some embodiments, the system is configured to print metal inks using the LDW, or any other suitable subsystem, such as but not limited to a dispensing subsystem, or an inkjet subsystem.

In other embodiments, the system is configured to produce various types of sensors and actuators, such as a thermal-based actuator, in the polymeric matrix. For example, the system is configured to (a) produce an electrical component, such as a resistor, e.g., below a cavity formed in the polymeric matrix, (b) dispense liquid having a coefficient of thermal expansion (CTE) larger than the CTE of the polymeric matrix, and (c) fixate a flexible membrane on top of the liquid dispensed in the cavity.

In some embodiments, in response to applying a certain voltage level to the sample, the resistor heats up, which expands the volume of the liquid and causes a thermal-based actuation accomplished by a protrusion of the flexible member out of the polymeric matrix. Other printable actuators are of the bi-metallic type which are generated by the LDW apparatus as part of a buildup process for producing the aforementioned 3D products of other objects.

In some embodiments, the system is further configured to control one or more of the thermal, electrical and mechanical properties of various sections of the sample, by forming in the polymeric matrix cavities having various sizes and shapes, and filling these cavities with selected liquid and/or solid substances having desired thermal, electrical and mechanical properties. The embedded solids may comprise, for example, any suitable type of micro-electro-mechanical (MEMS) sensors or actuator devices or any other micron scale electrically functional device, also for example power sources such a micro-batteries or super-capacitors.

The disclosed techniques can be used for producing complex products by conducting the entire production process with the sample retained in the vat. Such products are of special interest for example also in the emerging advanced electronics packaging industry. Moreover, the disclosed techniques improve the quality of the complex product and reduce production costs and the amount of chemical waste due to conducting all processes with the sample retained in the vat.

### System Description

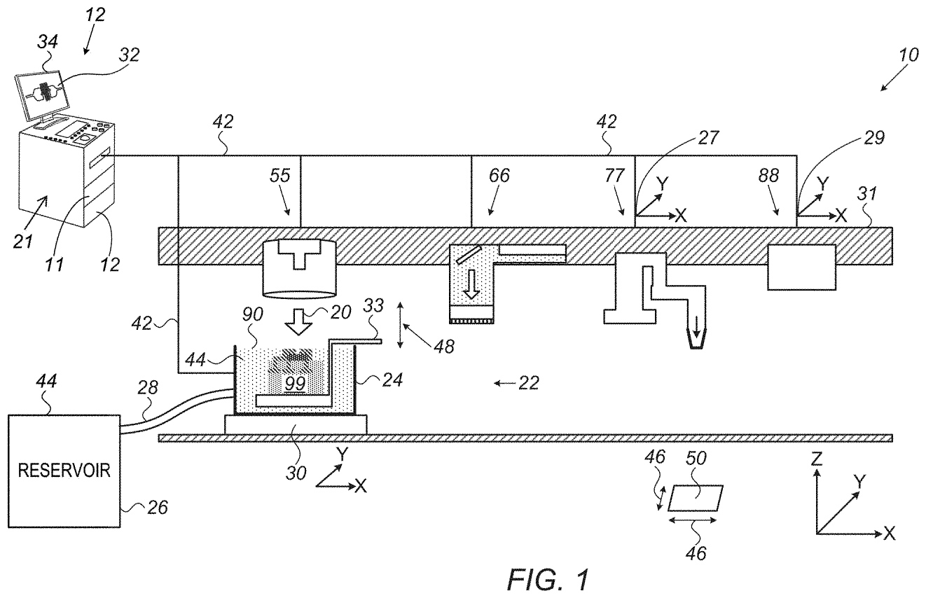

FIG. 1 is a schematic side view of a system 10 for manufacturing various types of electronic and optoelectronic devices, in accordance with an embodiment of the present invention. In some embodiments, system 10 comprises a stereolithography vat assembly, referred to herein as SLV 22 comprising a vat 24 and a photosensitive liquid 44 supplied to vat 24 from a reservoir 26 via a tube 28.

In some embodiments, photosensitive liquid 44 may comprise chemical moieties photopolymerizable to form epoxy or silicone polymers, or polyimide, or polyurethanes or polydicyclopentadiene, or photosensitive polymerizable silanes, or any other suitable type of photopolymerizable moietie.

In some embodiments, system 10 comprises a motorized z-stage, referred to herein as a mount 33 having a sample coupled thereto. In an embodiment, mount 33 is configured to move sample 99 relative to an upper surface 90 of liquid 44. In the example configuration of FIG. 1, mount 33 is configured to move sample 99 along a z-axis, as shown by a double-headed arrow 48, and to expose at least part of sample 99 to air or to any other suitable type of fluid and/or solid in the surrounding environment of upper surface 90 of liquid 44.

In some embodiments, system 10 comprises a motorized xy-stage, referred to herein as a mount 30, which is configured to move vat 24 in a controlled and uniform (e.g., smooth) motion along an x-axis and/or a y-axis (shown as double-headed arrows 46) of an xy-plane 50.

In some embodiments, system 10 comprises a stereolithography illumination assembly, referred to herein as SLI 55, which is coupled to a chassis 31 and is configured to illuminate at least upper surface 90 of liquid 44.

In some embodiments, SLI 55 is configured to project an image 20 on upper surface 90 of liquid 44, as will be described in detail below. In such embodiments, SLI 55 is configured to project image 20 aligned with an object buildup of sample 99 so as to polymerize at least part of liquid 44 located in close proximity to upper surface 90.

In other embodiments, SLI 55 is configured to scan upper surface 90 using one or more laser beams, or using any other suitable method for illuminating upper surface 90 of liquid 44.

In the context of the present disclosure and in the claims, the term “illuminating” refers to projecting image 20 or directing one or more light beams, for example, on liquid 44. In the context of the present disclosure and in the claims, the terms “illuminating,” “directing” and “projecting” are used interchangeably.

In such embodiments, SLI 55 is configured to project image 20 having a desired pattern on surface 90 of liquid 44, so as to form the pattern by polymerizing at least part of liquid 44 located in close proximity to upper surface 90.

In some embodiments, liquid 44 may comprise an ultraviolet (UV) photosensitive resin, such as photosensitive epoxy, or silicone, or any other type of UV sensitive monomeric or oligomeric resin, or any other suitable type of material. Such materials, which are readily polymerized upon exposure to the UV light, are provided for example, by Engineered Materials Systems Inc. (EMS) (Delaware Ohio, USA) and by EMS-NAGASE founded after shares of EMS were acquired by Nagase & Co, (Osaka, Japan).

In such embodiments, the projected light of image 20 may comprise UV light illuminating upper surface 90 of liquid 44, which is polymerized in accordance with a predefined pattern formed layer by layer as will be described in detail below.

In some embodiments, SLI 55 may comprise one or more laser diodes or one or more high-power light-emitting diodes (LEDs) configured to emit two or more wavelengths or ranges of wavelengths (e.g., having wavelengths of about 375 nm-405 nm) so as to control the depth, rate and other parameters of the polymerization process.

In some embodiments, SLI 55 is configured to project image 20 on upper surface 90 using a digital light processing (DLP) projector having about 1 Mega pixels or any other suitable number of mega pixels that defined the lateral span of the image for a given resolution of image 20. Note the tradeoff between lateral resolution and the illumination field size. For example, a 30 μm pixel size DLP projector may have an illumination field size of about 30 mm. Such DLP projectors are provided, for example, by Texas Instruments (Dallas, Tex.). Additionally or alternatively, SLI 55 may comprise any suitable type of a laser scanner (not shown).

In some embodiments, the polymerization of liquid 44 forms a solid layer, also referred to herein as a polymeric matrix, at upper surface 90, the thickness of the solid layer may be determined by various parameters of projected image 20, the properties of liquid 44, and other parameters, such as but not limited to light intensity, illumination duration, and absorption depth of the liquid. In some embodiments, after the layer, also referred herein as a top layer, at upper surface 90 of liquid 44, has been polymerized to a predetermined thickness, mount 33 moves sample 99 along the z-axis to immerse at least part of sample 99 in liquid 44, and SLI 55 illuminates liquid 44. The immersion and illumination processes repeat so as to form the desired pattern in according with a patterning buildup plan. The stereolithography process is further described in more details below.

In some embodiments, system 10 comprises a laser direct writing and/or component embedding subsystem and/or laser ablation subsystem, referred to herein as LDW 66, which is coupled to chassis 31 and is configured to deposit various types of materials (typically metallic layers) on the surface of sample 99. LDW 66 may apply various techniques and processes, such as but not limited to laser-induced forward transfer (LIFT).

In a LIFT process, one or more laser beams are directed to pass through a transparent donor substrate (not shown) and to impinge on one or more donor films deposited on a lower surface of the donor substrate that is facing sample 99. The impinged laser beam ejects droplets of the donor films that are landing at a predefined position on a surface of sample 99.

In the example of FIG. 1, the laser beam is reflected from a mirror or any other suitable beam reflection apparatus and is directed to the donor substrate. In other embodiments, the laser beam may be aimed directly from the laser to the donor substrate through an optical apparatus configured to set some of the properties of the incident beam as will be briefly described in some embodiments below.

In other embodiments, LDW 66 is configured to print non-conducting materials, such as dielectric layers and adhesives.

In yet other embodiments, LDW 66 is further configured to function as a laser micromachining station. Using the same laser source, or an additional laser type as required, to locally machine the printed material as required. For example, for drilling holes, and/or for removing undesired material, polymer or metal. Also, laser surface treatment is sometimes required to improve adhesion of the printed material. For example, this is typically achieved by polymer surface roughening to improve the adhesion of a laser printed metal track or trace on top of the pretreated polymer area, or in some cases removal of undesired oxide layer. The oxide removal may be required, for example, before printing contact metals on the top surface of the aforementioned metal pads.

Various processing methods of LIFT and other component embedding techniques are known, some described in detail, for example in Serra, Pere & Piqué, Alberto. (2018). Laser-Induced Forward Transfer: Fundamentals and Applications. Advanced Materials Technologies. 4. 1800099. 10.1002/admt.201800099 and in U.S. Patent Application Publication US20170189995, and in PCT Publication WO2019138404, whose disclosures are all incorporated herein by reference.

In some embodiments, system 10 comprises a pick and place subsystem, referred to herein as PP 77, which is configured to pick a device from any suitable substrate, and to place the device at a predetermined position on a surface of sample 99. Additionally or alternatively, PP 77 is further configured to pick and place any other type of a solid object, such as but not limited to one or more types of component, and/or any other suitable type and size of a solid item. PP 77 may comprise any suitable pick and place subsystem, such as a 4-axes REBEL-S6 SCARA robot, produced by Comau (Grugliasco, Italy) or any other suitable product or subsystem. Moreover, PP 77 may comprise a camera and image processing and registration algorithms for enhancing the spatial and vertical accuracy of the picking and placing operation.

In some embodiments, PP 77 is coupled to chassis 31 and comprises a mount 27, which is configured to adjust the position of PP 77 in xy plane. Mount 29 may be controlled, for example, using a processor 11 described below.

In some embodiments, system 10 may comprise a subsystem 88 configured to apply any other suitable process to sample 99. For example, subsystem 88 may comprise any suitable type of an inspection and/or metrology subsystems (e.g., optical-based), a laser ablation subsystem, a drilling subsystem, a sawing and/or dicing subsystem, a dispensing subsystem of conductive and non-conductive materials (e.g., adhesives), a liquid suction subsystem, a laser-based micromachining subsystem, an annealing/melting/curing heating subsystem (e.g., laser-based infrared), or any other suitable processing or inspection/metrology and image processing subsystem, or testing modules such as electrical testing. Note that system 10 may comprise one or more subsystems 88, each of which comprising at least one subsystem mentioned in the list above.

In some embodiments, subsystem 88 is coupled to chassis 31 and comprises a mount 29, which is configured to adjust the position of subsystem 88 in xy plane. Mount 29 may be controlled, for example, by processor 11.

In some embodiments, system 10 comprises a control console 12, which is configured to control multiple subsystems and assemblies of system 10, such as but not limited to SLV 22, SLI 55, LDW 66, PP 77, mounts 30 and 33, and any suitable type of subsystem 88 described above.

In some embodiments, console 12 comprises processor 11, typically a general-purpose computer, with suitable front end and interface circuits for interfacing, via cables 42, with controllers (not shown) of the aforementioned subsystems and assemblies, and for exchanging signals therewith.

In some embodiments, processor 11 and the controllers may be programmed in software to carry out the functions that are used by system 10, and store data for the software in a memory 21. The software may be downloaded to processor 11 and/or to one or more of the controllers in electronic form, over a network, for example, or it may be provided on non-transitory tangible media, such as optical, magnetic or electronic memory media.

In some embodiments, console 12 comprises a display 34, which is configured to display data and images, such as an image 34 received from processor 11, or inputs inserted by a user (not shown) using input devices 40.

In some embodiments, processor 11 is configured to control mounts 30 and 33 to move SLV 22 relative to the subsystems and assemblies coupled to chassis 31. Processor 11 is further configured to control each of the subsystems and assemblies described above to carry out a sequence of processes so as to produce an integrated electronic and/or optoelectronic device and/or product. Examples of such processes and process sequences are depicted in detail below.

In other embodiments, at least one of SLI 55, LDW 66, PP 77 and subsystem 88 may be coupled to a chassis different than chassis 31. For example, SLI 55 may be coupled to chassis 31, and LDW 66, PP 77 and subsystem 88 may be coupled, each, to a different respective chassis. This configuration may be used, for example, for improving the operational flexibility of SLI 55, LDW 66, PP 77 and subsystem 88 of system 10.

This particular configuration of system 10 is shown by way of example, in order to illustrate certain problems, such as integrating multiple devices and processes in a single product, that are addressed by embodiments of the present invention and to demonstrate the application of these embodiments in enhancing the performance of such a system. Embodiments of the present invention, however, are by no means limited to this specific sort of example system, and the principles described herein may similarly be applied to other sorts of production and/or engineering and/or research systems.

### Embedding an Electrical Trace in a Polymerized Sample

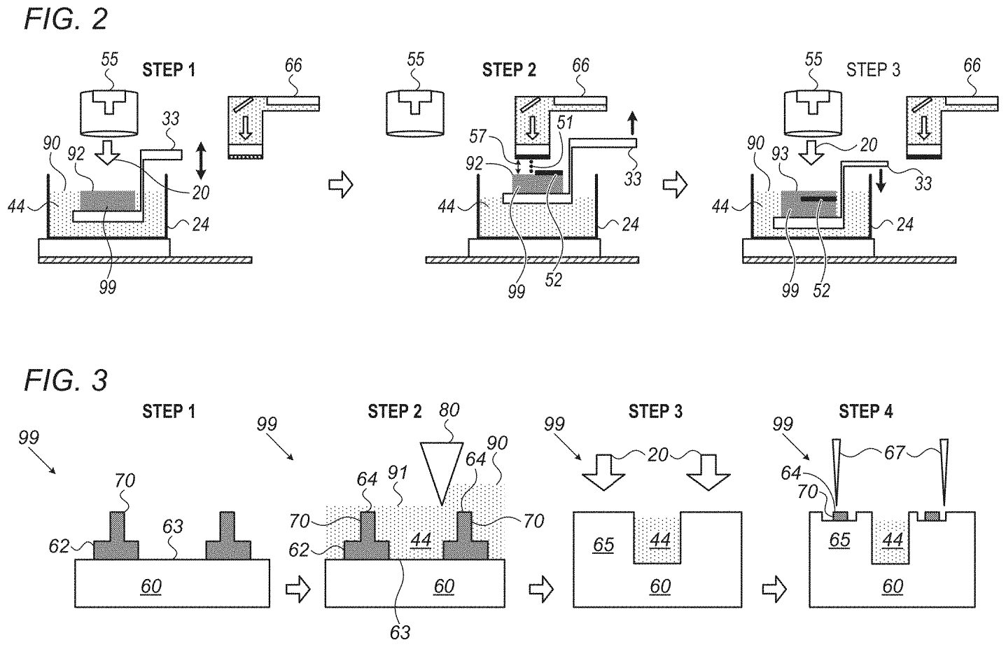

FIG. 2 is a diagram that schematically illustrates a a method and process sequence for producing and embedding an electrical trace 52 in a polymeric matric of sample 99, in accordance with an embodiment of the present invention. The process begins at a step 1 with processor 11 (a) controlling mount 30 to position sample 99 aligned with or in close proximity to SLI 55 in z-axis, (b) controlling mount 33 to move sample 99 along z-axis such that sample 99 is fully-immersed in a predefined thickness of liquid 44, and (c) controlling SLI 55 to project image 20 aligned with the object buildup on sample 99 and to polymerize an additive layer of sample 99 having a top surface 92.

In some embodiments, step 1 is concluded when the additive layer having pattern on top surface 92 in a solid state as part of sample 99. As will be described in detail below, at a thickness of up to about 50 μm, the thickness of liquid 44 typically corresponds to the thickness of the polymerized additive layer. In such embodiments, processor 11 controls SLI 55 to illuminate liquid 44 sufficiently for polymerizing a predetermined pattern corresponding to that specific layer, to the entire thickness of liquid 44 between the surface of sample 99 and the previous top layer. In an embodiment, after concluding step 1, top surface 92 of sample 99 may be flush with upper surface 90 of liquid 44.

In the context of the present disclosure and in the claims, the term “polymeric matrix” refers to any type of solid polymer layer produced by polymerizing liquid 44 using SLI 55 or any other suitable type of polymerizing process, for example as an additional thermal treatment, during or following the illumination session. Such polymer layers and processes for producing thereof are described in detail in FIGS. 3-9 below.

At a step 2, processor 11 controls (a) mount 33 to move sample 99 and to position top surface 92 at a predefined distance 57 from the aforementioned one or more donor films of LDW 66 (this is the case of LIFT printing only), and (b) LDW 66 to print electrical trace 52 by directing metal droplets 51 from the one or more donor films to the aforementioned predefined position at top surface 92.

In some embodiments, processor 11 may control the motion of mount 33 based on the specified volume of objects immersed into liquid 44. Additionally or alternatively, processor 11 may control mount 33 based on a sensed level of liquid 44 in vat 24, which is received from a sensing subsystem (not shown) integrated in SLV 22.

In some cases, LIFT jetting of molten metal droplets (that is carried out at hundreds or thousands centigrade) on the surface of organic polymers (such as polymerized liquid 44) may have insufficient adhesion of the printed material (e.g., electrical trace 52) to the surface of the polymerized layer. The insufficient adhesion may affect the quality (e.g., ability to control the dimensions of electrical trace 52) and reliability (e.g., delamination or shifting of electrical trace 52 relative to the surface of the polymerized layer) of sample 99. In the context of the present disclosure and in the claims, the terms “surface of the polymerized layer” and “polymer surface” are used interchangeably and refer to any surface of a polymerized layer having a layer, such as electrical trace 52, printed thereon or any other type of layer, device or component applied thereto or mounted thereon using any suitable technique as will be described, for example, in FIGS. 3-9 below.

In some embodiments, system 10 is configured to overcome this limitation using various techniques described herein. In an embodiment, system 10 may print on the surface of the polymerized layer an adhesion layer before producing electrical trace 52 by LDW 66. For example (i) printing metal alloys having a relatively low melting temperature, e.g. solder or other metal alloys having a melting temperature below 400° C., and/or (ii) printing a rheological adhesion layer, for example a paste loaded with micron scale particles. The low droplet temperature overcomes a recoil effect typical to high temperature metal droplet as they impinge on a polymeric surface. The recoil dislocates the droplets away from the intended printing position and often renders the droplets sufficiently cold when they land again on the surface which also gives rise to poor adhesion.

In other embodiments, system 10 may perform a laser pretreatment process that comprises patterning in the polymerized layer cavities and/or grooves of the designed pattern of electrical trace 52, and subsequently LDW 66 may fill the cavities and/or grooves with metal droplets and build up electrical traces 52. For example, the designed pattern may have a typical width (e.g., along x-axis or y-axis) smaller than about 10 μm and a typical depth of about 2 μm-5 μm.

In other embodiments, the adhesive force between electrical trace 52 and the surface of the polymerized layer may be improved by roughening the surface of the polymerized layer, for example, using a laser for ablating the surface of the polymerized layer.

In alternative embodiments, the adhesion may be improved by depositing micron-scale particles, using a particle dispenser, for coating the surface of the polymerized layer with the thin layer of particles.

In these embodiments, typical particle size is on the order of the LIFT printed droplet size (e.g., about 5 μm-15 μm) and the particle density is on the order of about 20%-50% of the area of the surface of the polymerized layer. The particles may comprise any suitable material, such as but not limited to glass beads, diamond powder, polymeric powder, and various types of ceramic particles.

In some embodiments, system 10 is configured to spread the thin powder layer on top of the surface of the polymerized layer. For example, system 10 may comprise a dispensing subsystem or an ink-jetting subsystem, which are configured to locally print a diluted solution of particle suspension in a highly volatile solvent. After depositing the diluted solution, the solvent typically evaporates and the particles remain on the surface of the polymerized layer.

In some embodiments, the dispensing and ink-jetting subsystems are configured to direct the aforementioned diluted solution to predefined locations on the surface of the polymerized layer, such as the locations intended for applying the LIFT print (e.g., electrical trace 52). Note that the material of the diluted solution are selected such that none of them or any combination thereof may interfere with the buildup of the polymerized layer. Moreover, these materials may improve the adhesion between the polymerized layers and other materials coupled to or deposited, for example on surface 92 of sample 99.

In other embodiments, the adhesive force may be further improved by adding the diluted solution, or any other suitable materials, to liquid 44 so as to form a stable suspension with liquid 44. In an embodiment, the stable suspension may be obtained by adapting the surface the aforementioned particles so as to obtain good wetting between the particles and liquid 44.

In alternative embodiments, system 10 may apply any other suitable method for roughening the surface of the polymerized layer so as to improve the adhesion with electrical trace 52.

At a step 3, processor 11 controls (a) mount 30 to position sample 99 aligned, in z-axis, with a position of SLI 55, (b) mount 33 to move sample 99 along z-axis such that sample 99 is fully-immersed in liquid 44, and (c) SLI 55 to project image 20 on sample 99 so as to polymerize a pattern in liquid 44, and to form on sample 99 an additive patterned layer having a top surface 93.

In some embodiments, after concluding step 3, surface 92 of step 1 is embedded within the bulk of sample 99 and having electrical trace 52 disposed thereon, and liquid 44 is polymerized so as to produce the additive layer having top surface 93. Note that the process sequence of FIG. 2 forms electrical trace 52 embedded in sample 99 while sample 99 remains within vat 24, without any transference and/or cleaning steps of sample 99.

Moreover, sample 99 remains within SLV 22 during the entire process sequence of FIG. 2, and during additional processes carried out by system 10 as will be described in detail in FIGS. 3-9 below.

### Forming Interlayer Electrical Interconnects in a Polymeric Matrix

FIG. 3 is a diagram that schematically illustrates a method and process sequence for producing and embedding a three-dimensional (3D) metallic structure in a polymeric matrix, in accordance with an embodiment of the present invention. The method begins at a step 1 with printing one or more 3D metallic structure, each of which comprising one or more pads 62 and one or more pillars 70, on a surface 63 of a substrate 60. Note that substrate 60 may be a substrate of sample 99 as shown in FIG. 3, or a substrate of any other suitable sample. Moreover, FIG. 3 depicts a section of sample 99, which may differ from other sections of sample 99 depicted in FIGS. 1 and 2 above.

In some embodiments, the production of pads 62 and pillars 70 may be carried out using LDW 66 of system 10, which may apply the LIFT process described in FIGS. 1 and 2 above or in any other suitable process. In some embodiments, the 3D structure of pillars 70 may be produced by jetting, from a donor (not shown) of LDW 66, metallic droplets at an angle, using any suitable technique, such as but not limited to: (a) shaping an asymmetric laser beam of LDW 66, or (b) having a donor layer on a multi-facet donor substrate, or (c) tilting the donor substrate. or any other suitable combination thereof Such techniques are described in detail, for example in U.S. Patent Application Publications 2017/0306495 A1 and 2018/0193948 A1, whose disclosures are all incorporated herein by reference.

Further examples of pillar buildup using LIFT are provided by Zenou et al., in “Printing of metallic 3D micro-objects by laser, induced forward transfer,” OPTICS EXPRESS, Vol. 24, No. 2, 1431, (2016); and by Claas Willem Visser et al., in “Toward 3D Printing of Pure Metals by Laser-Induced Forward Transfer,” ADVANCED MATERIALS, Vol 27, Issue 2015, P4087, which are all incorporated herein by reference. In other embodiments, the production of pads and pillars 70 may be carried out using any other suitable metal deposition and/or patterning techniques.

In other embodiments, substrate 60 may comprise pads 60, so that at step 1 LDW 66 may print a pillar 70 at a predefined position on a respective pad 62. Note that processor 11 controls mounts 30 and 33 to move substrate 60 relative to LDW 66 along xyz axes for directing the metal droplets to predefined positions.

In other embodiments, subsystem 88 may comprise a registration metrology subsystem for measuring overlay between the positions of a pillar 70 and a respective pad 62.

Note that in the context of the present disclosure, the movements of the samples and/or substrates in the embodiments described herein, are carried out when the samples and/or substrates are held in vat 24 of SLV 22. In principle, it is possible to extract a sample out of vat 24, but the inventors found that in the typical use cases of the process sequences described herein, retaining the sample in vat 24 reduces the total cycle time of the process sequence.

Moreover, the inventors found that retaining the sample in vat 24 reduces setup time, improves temperature and viscosity control, reduces contamination and other type of defects, and increases the process uniformity.

In some embodiments, pillars 70 or any other type of vertical metal interconnects (VMI) or 3D structures produced by LDW 66, may be high (e.g., tens of microns, or hundreds of microns, or a few millimeters) along z-axis and have a thin diameter (e.g., about 20 μm or 10 μm or smaller) or length and width along x and y axes. Such VMI geometries are also referred to herein as high aspect ratio (HAR) VMI that need suitable mechanical fixation as will be described below. Note that LDW 66 is configured to print pillars having any diameter larger than 10 μm.

In an embodiment, LDW 66 is configured to produce such HAR structures because the droplets ejected from the aforementioned donor of LDW 66 solidify almost immediately when touching the surface of sample 99 (e.g., surface 63 or the metallic surface of the previous droplets already deposited on pads 62 or pillars 70).

In some embodiments, system 10 comprises a wiper assembly 80, which is coupled to any of mounts 30 or 33 and is configured to remove at least part of liquid 44 and/or to flatten the upper surface of liquid 44.

In some embodiments, at a step 2, processor 11 controls mounts 30 and 33 to: (a) move SLV 22 relative to SLI 55 so as to immerse sample 99 in liquid 44 by lowering the position of sample 99 along z-axis and having a thickness of liquid 44 defined by the distance between surfaces 90 and 63, (b) move wiper 80 to reduce the thickness of liquid 44 having a different upper surface 91, such that the reduced thickness is defined as the distance between surfaces 63 and 91.

Note that after the wiping, an upper surface 64 of pillar 70 may be flush with surface 91 or may be still immersed in liquid 44, but the distance between surfaces 64 and 91 is substantially smaller than the distance before wiping, measured between surfaces 64 and 91.

In other embodiments, system 10 may comprise any other type of subsystem configured to reduce the thickness of liquid 44 using any other liquid removal technique.

In alternative embodiments, processor 11 is configured to control mount 33 to immerse sample 99 such that surface 64 extends above surface 90 of liquid 44 (e.g., about 10 μm or 20 μm). In such embodiments, the wiping process described above may be omitted.

In an embodiment, wiper 80 may comprise soft material, such as silicone rubber or another suitable type of polymer. Additionally or alternatively, wiper 80 may comprise any suitable type of harder material, such as any suitable type of polyimide, e.g., Kapton®, or stainless steel. Note that any of the aforementioned materials in this embodiment, is configured to reduce the thickness of liquid 44 such that surface 64 may protrude out of the upper surface of liquid 44.

Note that the processes described above may depend on various parameters, such as but not limited to the rheology of liquid 44, the surface tension and viscosity of liquid 44, and on various parameters of the immersion process.

In some embodiments, the viscosity of liquid 44 may be controlled using various techniques. For example, the viscosity may be reduce by two orders of magnitude by heating liquid 44 from room temperature (e.g., about 25° C.) to about 60° C. In an embodiment, the heating may be carried out using any suitable technique. For example, irradiating the upper layers of liquid 44 using infrared (IR) illumination (or any other suitable illumination) may obtain rapid and accurate control of the temperature of at least the upper layers of liquid 44.

In some cases, some liquid 44 may remain on surface 64 of pillar 70. The undesired remaining of liquid 44 may be removed from surface 64 using any suitable technique, such as but not limited to ablation using the laser of LDW 66. Note that the removal of the residues may be carried out, e.g., using the laser of LDW 66, after the polymerization process, when the residues are in solid state as will be described in steps 3 and 4 below. Additionally or alternatively, system 10 is configured to remove the residues in liquid state using any other suitable technique.

In the context of the present disclosure, the terms “about” or “approximately” for any numerical values or ranges indicate a suitable dimensional tolerance that allows the part or collection of components to function for its intended purpose as described herein. More specifically, “about” or “approximately” may refer to the range of values±20% of the recited value, e.g. “about 90%” may refer to the range of values from 71% to 99%.

At a step 3, processor 11 controls SLI 55 to project image 20 aligned with the object buildup to the upper layer of liquid 44 located between surfaces 91 and the 3D structure comprising pads 62 and pillars 70. As described in step 3 of FIG. 2 above, the illumination polymerizes liquid 44 and forms a solid layer 65, which contains at least some of pads 62 and pillars 70.

In some embodiments, layer 65 provides HAR VMI structures, such as pillars 70, with mechanical fixation that improves the quality and reliability of sample 99. In other words, the combination of pillars 70 and layer 65 provides vertical metallic interconnects which are highly stable since the metal is tightly embedded in a polymeric matrix. Note that liquid 44 remains at the locations not illuminated by SLI 55.

In some embodiments, the laser of LDW 66 may be used for ablating and/or patterning solid layers of sample 99 as will be described herein. In other embodiments, system 10 comprises a laser ablation subsystem (not shown) coupled to chassis 31, for example, instead of subsystem 88. At a step 4, processor 11 controls mounts 30 and 33 to bring pillar 70 in close proximity to the laser of LDW 66, or the laser of the laser ablation subsystem. Subsequently, processor 11 controls the laser to direct one or more beams for ablating layer 65 located in close proximity to pillar 70 so as to reveal at least surface 64 of pillar 70. In some embodiments, the laser ablation subsystem may comprise a Q-switched solid-state laser or a pulsed fiber laser with short pulses (e.g. nanoseconds or sub-nanoseconds) configured to emit one or more wavelengths (e.g., 355 nm or 532 nm) with a few micro-Joules of pulse energy and spot sizes typically on the order of the droplet diameter or smaller for controlling the depth (along z-axis) of ablating layer 65.

In some embodiments, step 4 terminates the process sequence of FIG. 3. In other embodiments, the process sequence of FIG. 3 may comprise additional process steps. For example, after performing the laser ablation, system 10 is configured to clean the ablated surface, using any suitable type of surface cleaning technique.

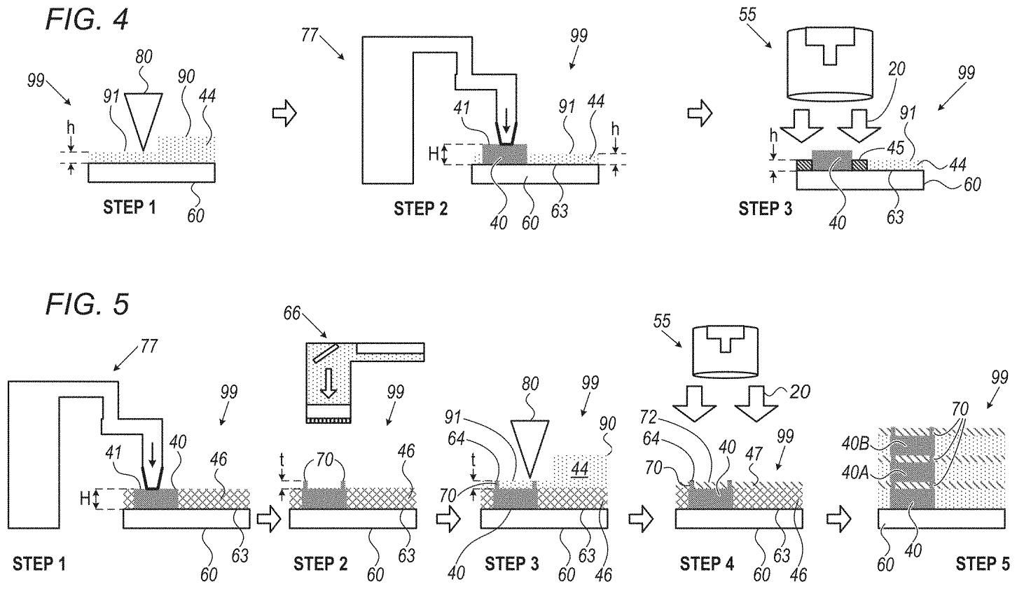

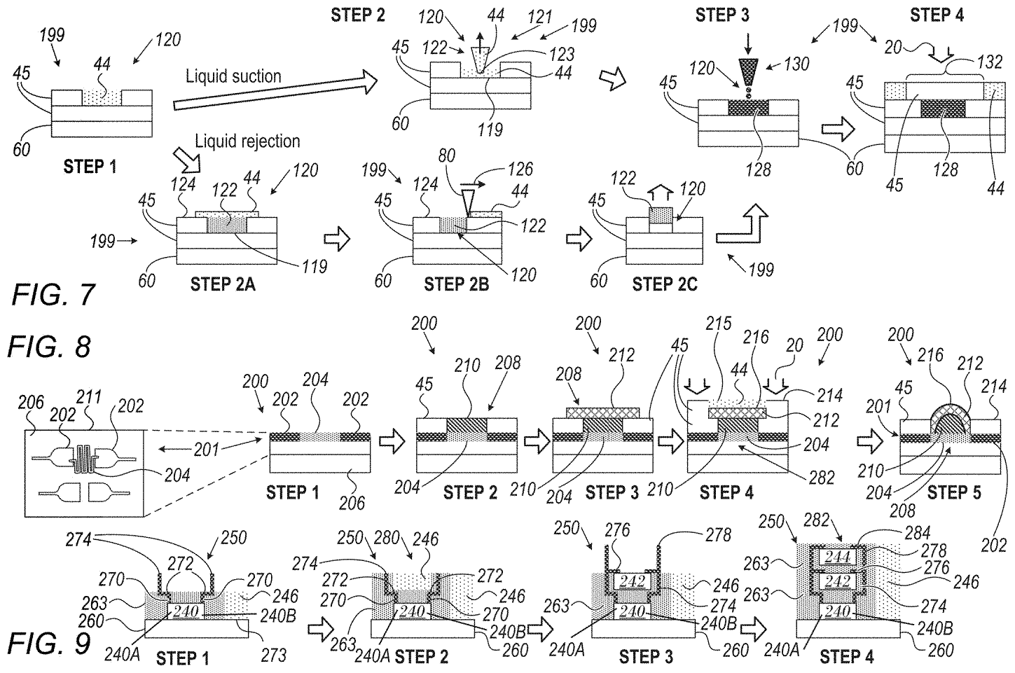

In some embodiments, the remaining liquid 44 may continue with sample 99 to additional process sequences. In other embodiments, before or after step 4, system 10 is configured to process at least a portion of the remaining liquid 44 as will be described, for example in FIGS. 4-6 below, and/or to evacuate at least another portion of the liquid 44 remaining across sample 99, as will be described in detail in FIG. 7 below. Note that sample 99 remains within SLV 22 during the entire process sequence of FIG. 3.

In some embodiments, system 10 is configured to produce one or more HAR VMI structures, such as pillars 70, by repeating steps 1-4. In such embodiments, system 10 produces a first pillar 70 at a height that corresponds to the polymerization thickness of a first layer 65, and reveals surface 64 of first pillar 70 using laser ablation of any other technique. Subsequently, system 10 repeats the process by producing, on top of surface 64, a second pillar (using the techniques described in step 1 above) and further produces, on top of first layer 65, a second layer (using the techniques described in steps 2-3 above) so as to provide second pillar 70 with mechanical support, and reveals the top surface of second pillar 70 using the techniques described in FIG. 4 above.

By repeating the process of FIG. 3 multiple times, system 10 is configured to produce VMI structures having very high aspect ratio. In other embodiments, system 10 is configured to produce, between vertical pillars such as first and second pillars 70, a thin conductive (e.g., metallic) layer having a width (in a xy plane shown in FIG. 1) larger than the width of pillars 70. For example, a width similar to that of pad 62. Such layer is configured to electrically connect between first and second pillars 70, and to maintain the specified electrical conductivity of the VMI structure comprising first and second pillars 70 by compensating for any registration error between first and second pillars 70.

In other embodiments, the metallic structure may comprise any suitable 3D structure that may be at least partially different from pads 62 and pillars 70. Such 3D structure may comprise metal walls, which are configured to dissipate heat during the operation of the end-product, and/or to improve the mechanical strength of the end-product, and/or to serve as a magnetic shield or an electrical shield. Moreover, such 3D structures may be used as sensor and/or as actuators, as will be described in detail in FIG. 8 below.

Note that sample 99 remains within SLV 22 during the entire process sequence of FIG. 3.

### Fixating an External Device in a Layer of a Polymeric Matrix Using a Stereolithography Process

FIG. 4 is a diagram that schematically illustrates a method and process sequence for fixation of a 3D electronic device 40 in a polymeric matrix, in accordance with an embodiment of the present invention. In the context of the present invention and in the claims, the term “3D electronic device” 40, is also referred to herein as “device” 40 for brevity, and is referred to any type of an electronic device, an optoelectronic device, a sensing device, a power source such as a battery, a passive electrical component, micron-scale electro-mechanical system or any other suitable type of device.

Note that FIG. 4 depicts a section of sample 99, which may differ from other sections of sample 99 depicted in FIGS. 1-3 above.

The process sequence begins at a step 1, with immersing substrate 60 in liquid 44 and reducing the width of liquid 44 to a thickness “h” by wiping at least a portion of liquid 44, using the techniques described in step 2 of FIG. 3 above.

At a step 2, a robotic arm of PP 77 picks device 40 from an external substrate or tray (not shown) and places (i.e., positions) device 40 at a predefined position in sample 99, in the present example on surface 63 of substrate 60. Note that, when positioning device 40 on surface 63, the robotic arm of PP 77 has to apply force in z-axis in order to overcome the resistance of liquid 44, which depends, inter-alia, on the viscosity of liquid 44. In some cases, at least part of device 40 has to remain uncovered by the polymeric matrix. Therefore, in some embodiments, thickness “h” obtained by wiping liquid 44 at step 1 is thinner compared to a thickness “H” of device 40. In such embodiments, at least an upper surface 41 of device 40 is not immersed in liquid 44.

At a step 3, processor 11 controls mounts 30 and 33 to position device 40 in close proximity to SLI 55, and controls SLI 55 to project image 20 on the upper layer of liquid 44 located between surfaces 91 and 63. As described in step 3 of FIG. 2 above, the illumination polymerizes liquid 44 to form a pattern and, in the present example, forms a solid layer 45, which contains at least the part of device 40 positioned within thickness “h” of layer 45.

In some embodiments, the remaining liquid 44 may continue with sample 99 to additional process sequences.

In some embodiments, the process sequence described in FIG. 4 enables the fixation of device 40 in layer 45 having a smaller thickness than that of device 40, and the width (e.g., along x-axis or y-axis) and pattern of layer 45 is controllable by the positioning of projected image 20 on liquid 44 also polymerizing the liquid surrounding device 40. In other embodiments, layer 45 may have any other suitable thickness, larger or smaller than thickness “H” of device 40.

The techniques described in steps 1-3 above may be used for fixating and encapsulating un-packaged devices, also referred to as “bare dies,” having small thickness, e.g., smaller than about 100 μm.

In other embodiments, in addition to fixating device 40, system 10 is configured to illuminate liquid 44 in additional areas so as to produce a solid pattern, such as layer 45, at locations that are not in close proximity to device 40. In such embodiments, system 10 is configured to project an image that is fixating device 40 and producing the solid pattern at the same time. In other embodiments, the illumination may carry out the fixation and patterning described above at different times.

Note that sample 99 remains within SLV 22 during the entire process sequence of FIG. 4.

### Encapsulating Electronic Devices in a Polymeric Matrix and Revealing Electrical Interconnecting

FIG. 5 is a diagram that schematically illustrates a method and process sequence for packaging devices 40, 40A and 40B in a polymeric matrix, in accordance with an embodiment of the present invention.

Note that FIG. 5 depicts a section of sample 99, which may differ from other sections of sample 99 depicted in FIGS. 1-4 above.

The method begins at a step 1 with (a) immersing sample 99 in liquid 44 (not shown) having a thickness “H” similar to that of device 40, (b) using PP 77 for placing device 40 at a predefined position on substrate 60, and (c) forming a polymeric matrix, in the present example layer 46, using SLI 55 for polymerizing liquid 44 at selected locations of sample 99.

Note that layer 46 is similar to layer 45 of FIG. 4 above, but has a different thickness, for example layer 45 may have a thickness smaller than about 50 μm, or any other suitable thickness, and layer 45 may have a thickness larger than about 100 μm.

In some embodiments, step 1 of FIG. 5 applies techniques similar to the techniques described in FIG. 4 above, except for the wiping process that is performed at step 1 of FIG. 4, but is typically not needed in step 1 of FIG. 5.

Note that liquid 44 may be polymerized by absorption of the UV light of projected image 20, and therefore, longer exposure time is required for polymerizing liquid 44 having a thickness larger than about 50 μm. Moreover, due to the damping of UV light intensity in liquid 44, the UV exposure time may increase exponentially, and even in longer exposure times, the polymerization depth may be limited to less than the aforementioned thickness of about 100 μm.

In some embodiment, system 10 is configured to produce any suitable thickness of layer 46 by repeating steps for producing a solid layer 46 or a pattern thereof having a thickness of about 50 μm. The steps may comprise immersing sample 99 in liquid 44 having a thickness of about 50 μm, and polymerizing liquid 44 to produce solid layer 46 or a pattern thereof having a thickness of about 50 μm, as described in FIG. 3 above.

In some embodiments, system 10 may overcome this limitation using a method for partitioning step 1 into the following sequence of process sub-steps: (a) immersing sample 99 in liquid 44 having a thickness “h” (e.g., smaller than about 50 μm), (b) placing device 40 using PP 77, (c) polymerizing liquid 44 by UV illumination carried out by SLI 55, (d) immersing sample 99 in liquid 44 having a thickness “h” or any other thickness smaller than about 50 μm, and (e) polymerizing the liquid 44 by UV illumination carried out by SLI 55. The method may repeat sub-steps (d) and (e) until obtaining the required thickness of the polymerized layer.

In some embodiments, system 10 comprises the aforementioned sensing subsystem (not shown) for sensing the level of liquid 44, and thereby, measuring the thickness of liquid 44 immersing sample 99 in sub-steps (a) and (d). In such embodiments, processor 11 (or any controller of system 10) is configured to control mount 33 to move sample 99 along z-axis so as to obtain the desired thickness “h” that can be fully polymerized by SLI 55 (e.g., at sub-steps (c) and (e)) using a production-worthy illumination time.

In some embodiments, processor 11 is configured, based on the sensed level of liquid 44, to pump liquid 44 between reservoir 26 and vat 24. For example, processor 11 may hold thresholds indicative of the specified upper and lower levels of liquid 44 in vat 24. In such embodiments, processor may control a pump (not shown) to (a) flow liquid 44 from reservoir 26 into vat 24 when the level of liquid 44 is within or below the lower specified level, or (b) flow liquid 44 from vat 24 into reservoir 26 when the level of liquid 44 is within or above the upper specified level.

Additionally or alternatively, the polymerization depth may be increased or reduced by selecting a suitable chemical composition (for example adding absorbing dye to reduce depth) of liquid 44 in conjunction with a suitable illumination wavelength of SLI 55. In some embodiments, the chemical composition and illumination wavelength may also affect the duration of polymerization, which may affect the total cycle time of step 1.

At a step 2, processor 11 controls mounts 30 and 33 to position device 40 in close proximity to LDW 66. Note that device 40 has electrically conductive pads, also referred to herein as contact pads (not shown). Subsequently, processor 11 controls LDW 66 to print pillars 70 having a height “t” on the aforementioned contact pads as described in step 1 of FIG. 3 above.

At a step 3, processor 11 controls mount 33 to immerse sample 99 in liquid 44, and subsequently, controls wiper 80 to flatten surface 91 and to reduce the thickness of liquid 44 so as to obtain a thickness similar to height “t” of pillars 70. In such embodiments, after the wiping process, surfaces 91 and 64 are almost flush.

Note that the terms “height” and “thickness” refer to the size of layers along the z-axis, wherein thickness may refer to the size of a full layer (e.g., layer 46) and height may refer to the size of a patterned layer (e.g., pillars 70). In stereolithography, however, the so-called “full layers” are typically patterned, so that the terms “height” and “thickness” may be used interchangeably to show the size of a respective pattern along the z-axis.

At a step 4, processor 11 control mounts 30 and 33 to bring sample 99 in close proximity to SLI 55, and subsequently, controls SLI 55 to project image 20 on the upper layer of liquid 44. As described above, the illumination polymerizes liquid 44 and forms, at step 4, a solid layer 47 having an upper surface 72, which is slightly (e.g., about 10 μm) above surface 64 of device 40. As described in step 4 of FIG. 3 above, system 10 is configured to reveal at least surface 64 of pillar 70 so as to electrical connect pillars 70 with any device coupled thereto.

In some embodiments, after step 4 device 40 may be electrically connected, via pillars 70, to any device or electrical trace external to sample 99. In some embodiments, the techniques disclosed at steps 1-4 of FIG. 5 may be used for electrically connecting between devices of sample 99.

At a step 5, processor 11 repeats steps 1-4, and optionally additional processes, at least twice for vertically stacking devices 40A and 40B over device 40.

In some embodiments, each of devices 40, 40A, and 40B may comprise electrical contacts, such as through-silicon-via (TSV), contact pads or other suitable types of electrical conductors, configured to conduct electrical signals (a) between devices 40A, 40B and pillars 70 and (b) between device 40 and substrate 60.

In some embodiments, at least one of devices 40A and 40B may comprise pads facing substrate 60, referred to herein as “facing down.” In these embodiments, processor 11 is configured to control a dispenser, mounted on chassis 31, to apply electrically conductive adhesive (e.g. epoxy or silicone filled with metal), or solder, or any other suitable substance, to the aforementioned contact pads. These embodiments are described in further details in FIG. 9 below. Such electrical contacts may enable selective routing of signals between specific electrical or electronic elements (e.g., transistors or diodes, and/or memory cells and/or passive electrical elements of any of devices 40, 40A, and 40B), within the stack of devices 40, 40A, and 40B of sample 99.

The device stacking process sequence may comprise additional process steps, such as but not limited to surface preparation by cleaning or roughening and melting/annealing/curing, so as to improve the adhesion and electrical conductivity at interfaces between adjacent layers. Moreover, the device stacking process sequence may comprise additional metal patterning processes (e.g., LIFT processes carried out by LDW 66) as shown, for example, in FIG. 9 below. Note that sample 99 remains within SLV 22 of system 10 during the entire process sequence of FIG. 5.

### Packaging Multiple Components Having Different Dimensions

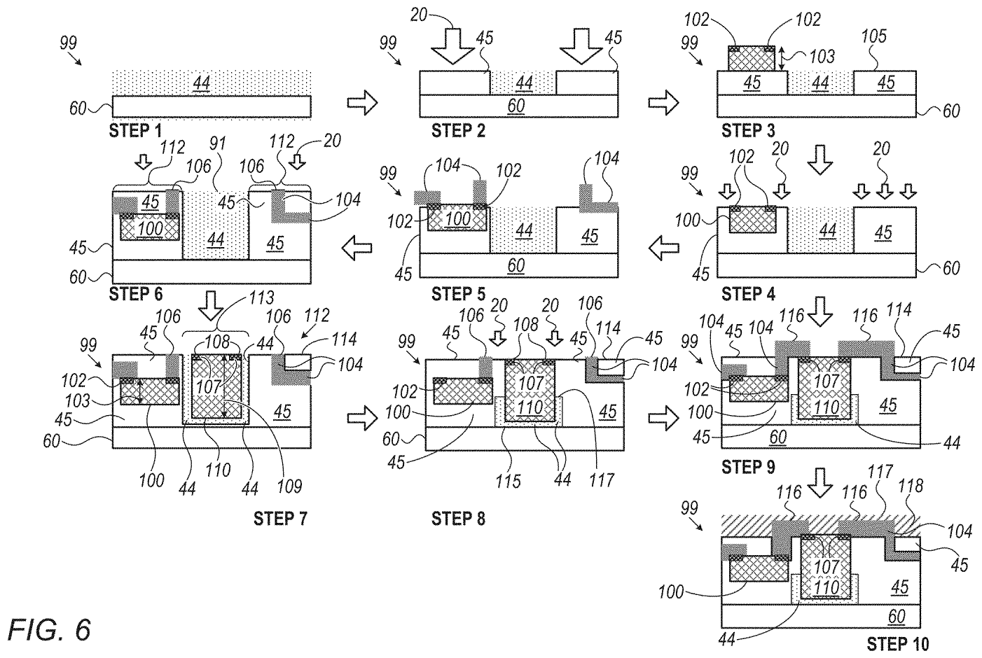

FIG. 6 is a diagram that schematically illustrates a method and process sequence for packaging multiple components having different dimensions in a polymeric matrix, in accordance with an embodiment of the present invention.

In the context of the present disclosure, and particularly in FIG. 6, the term “components” may refer to an active components, such as an electronic devices, or a passive component, such as electrical components (e.g., resistors, capacitors, or inductors), or any two-dimensional (2D) or 3D structures. Note that FIG. 6 depicts a section of sample 99, which may differ from other sections of sample 99 depicted in FIGS. 1-5 above.

The method begins at a step 1 with processor 11 controlling mount 33 to move along z-axis so as to immerse sample 99 in liquid 44.

At a step 2, processor 11 controls mounts 30 and 33 to position sample 99 in close proximity to SLI 55, and further controls SLI 55 to project image 20 to predefined locations of liquid 44 and form solid layer 45 by the polymerization process described, for example, in step 3 of FIG. 4 above.

In some embodiments, layer 45 may have a thickness of about 20 μm-50 μm so that step 2 may be carried out using a single illumination process. In other embodiments, layer 45 may have a thickness larger than about 50 μm (e.g., larger than about 100 μm), such that the formation of layer 45 may be carried out using any other suitable process. For example, using one of the process sequences for producing layer 46 as described in step 1 of FIG. 5 above.

At a step 3, processor 11 controls mounts 30 and 33 to position sample 99 aligned with PP 77, and further controls PP 77 to place a device 100 having a thickness 103, at a predetermined position on an upper surface 105 of layer 45. In an embodiment, device 100 comprises pads 102 configured to electrically connect device 100 with electrical traces as will be described herein in later process steps of FIG. 6, and further described in more detail in FIG. 9 below.

At a step 4, processor 11 controls mounts 30 and 33 to immerse device 100 in liquid 44 and to position sample 99 aligned with SLI 55. In some cases, system 10 may apply a wiping process, as described for example in step 3 of FIG. 5 above, for obtaining a specified thickness of liquid 44. Subsequently, processor 11 controls SLI 55 to project image 20 to predefined locations of liquid 44 and form solid layer 45 by the polymerization process described in step 3 of FIG. 4 above. Note that after concluding step 4, the position of device 100 is fixated within sample 99 by layer 45.

At a step 5, processor 11 controls mounts 30 and 33 to position sample 99 aligned with or in close proximity to LDW 66. Subsequently, processor 11 controls LDW 66 to print (or deposit using any other suitable technique) electrical traces 104 at predefined positions on the upper surface of sample 99, as described in step 2 of FIG. 2 and in step 2 of FIG. 5 above. In the present example, LDW 66 prints electrical traces 104 at selected locations on the upper surface of layer 45 and on the upper surface of pads 102, such that one or more of electrical traces 104 are electrically connected with pads 102 of device 100.

In some cases, the positioning accuracy of PP 77 may be insufficient and may cause registration errors within sample 99. For example, a registration error may occur in step 3 PP 77 may position device 100 at a position shifted from the specified position thereof, and at step 5 LDW 66 may print traces 104 at their specified position.

In some embodiments, system 10 may comprise an optical inspection subsystem, which may be coupled to PP 77, or to LDW 66, or instead of subsystem 88. The inspection subsystem is configured to scan the surface of sample 99, for example after step 3, and to check the actual position of device 100. In case of a positioning accuracy error, processor 11 may suggest an operator of system 10 to rework the placement of device 100 in sample 99, or may control LDW 66 to adjust the position of traces 104 so as to compensate for the placement error of device 100.

In other embodiments, at least some of electrical traces 104 may be used for dissipating heat generated during the operation of device 100 or for conducting heat from any other active or passive device. In some embodiments, device 100 may comprise any type of device or structure suitable for sample 99. For example, resistors, capacitors, inductors, batteries, dies made from silicon, gallium-arsenide or any other types of semiconducting substrates, and LEDs.

The heat conductance embodiments described above are particularly important for products, such as sample 99, comprising power devices, LEDs and high-power processing units. In such embodiments, some of electrical traces 104 may be coupled to a heat sink (not shown) and conduct the excess heat from device 100 to the heat sink. As such, the respective electrical traces 104 may have any suitable pattern that enhances the dissipation of excess heat from one or more devices of sample 99 to one or more heat sinks located in close proximity or coupled to sample 99.

At a step 6, processor 11 controls mount 33 to move sample 99 along z-axis so as to immerse sample 99 in liquid 44. In some embodiments, processor 11 controls wiper 80 to level upper surface 91 of liquid 44 with an upper surface 106 of electrical traces 104, using the technique described in step 3 of FIG. 5 above.

In some embodiments, processor 11 may control mounts 30 and 33 to position sample 99 aligned with or in close proximity to SLI 55, and further controls SLI 55 to project image 20 to sections 112 of sample 99 so as to polymerize liquid 44 and thereby form layer 45, as described, for example, in step 4 of FIG. 5 above.

In other embodiments, processor 11 may control mount 33 to position sample 99 sufficiently accurate along z-axis so as to have upper surface 91 flush with upper surface 106 without using wiper 80.

In alternative embodiments, processor 11 may retain electrical traces 104 immersed in liquid 44 by not using SLI 55 to project image 20 to sections 112 in step 6.

At a step 7, processor 11 controls mounts 30 and 33 to position sample 99 aligned with PP 77, and further controls PP 77 to place a device 110 having a thickness 109, at a predetermined position within a section 113 of sample 99. Note that section 113 is a cavity filled with liquid 44 so that by positioning device 110, a portion of liquid 44 (having about the same volume of device 110) overflows on a surface 114 of sections 112 surrounding section 113.

In some embodiments, processor 11 may apply wiper 80 for wiping the overflown liquid 44 away from surface 114. Note that the unwiped portion of liquid 44 may remain, together with device 110, within the cavity of section 113. In an embodiment, device 110 comprises pads 107 having an upper surface 108. Pads 107 are configured to electrically connect device 110 with electrical traces coupled to upper surface 108 as will be described herein in later steps of FIG. 6. In an embodiment, processor 11 is configured to control steps 5-7 described above, such that surfaces 106 and 108 are flush with one another.

In the example of FIG. 6, thicknesses 103 and 109 of respective devices 100 and 110 are both larger than a thickness of a stereolithographic process (which is about 20 μm-50 μm), but differ from one another, and are shown in a simplified manner for the sake of conceptual clarity.

As described in FIG. 1 above, SLI 55 is configured to emit two or more wavelengths or ranges of wavelengths so as to control the polymerization depth of liquid 44. For example, SLI 55 may obtain larger polymerization depth by illuminating liquid 44 with projected image 20 having a wavelength larger than 400 nm or using any other suitable wavelength or range of wavelengths.

In other embodiments, processor 11 may apply the same techniques described in steps 3-7 for packaging together multiple components having any other difference in shape and/or dimension.

At a step 8, processor 11 controls mounts 30 and 33 to position sample 99 aligned with or in close proximity to SLI 55, and further controls SLI 55 to project image 20 to section 113 so as to polymerize a portion of liquid 44 surrounding device 110 and thereby form layer 45, using the technique described in step 4 of FIG. 5 above. Note that due to the height of device 110 and the limited depth of the polymerization of liquid 44, which is located between surfaces 117 and 115, part of liquid 44 has not been polymerized.

In some embodiments, processor 11 may apply a thermal process to sample 99, e.g., by controlling the aforementioned annealing subsystem or any other suitable furnace subsystem coupled to chassis 31 instead of or in addition to subsystem 88. In such embodiments, the thermal process may form layer 45 by polymerizing the remaining portion of liquid 44. The thermal process may help fixating device 110 and is therefore also referred to herein as a “thermal fixation” process.

In other embodiments, the thermal process may be carried out at a later stage of the process, for example during a thermal curing step that may be carried out after concluding the production of sample 99.

In such embodiments, sample 99 may comprise materials that can be polymerized using both UV exposure and by thermal curing. Such materials are referred to herein as having a dual functionality or as having a dual curing mechanism.

At a step 9, processor 11 controls mounts 30 and 33 to position sample 99 aligned with or in close proximity to LDW 66. Subsequently, processor 11 controls LDW 66 to print (or dispose using any other suitable technique) electrical traces 116 at predefined positions on the upper surface of sample 99, as described in step 5 above. In the example of step 9, electrical traces 116 are printed on pads 107 and on electrical traces 104, so as to electrically connect device 110 with device 100 and with external entities not shown in FIG. 6.

In some embodiments, system 10 is configured to check for registration errors using the aforementioned optical inspection subsystem, and if needed, to compensate for such errors using the techniques described in step 5 above, or any other suitable technique.

At a step 10 that concludes the method shown in FIG. 6, processor 11 controls mount 33 to move sample 99 along z-axis so as to immerse sample 99 in liquid 44. Subsequently, processor 11 controls mounts 30 and 33 to position sample 99 aligned with or in close proximity to SLI 55, and further controls SLI 55 to project image 20 to a surface 117 as to encapsulate sample 99 by polymerizing liquid 44 and forming an encapsulation layer 118. In some embodiments, step 10 may comprise wiping the upper surface of liquid before the polymerization process, so as to control the thickness of layer 118.

In some embodiments, encapsulation layer 118 may be similar to layers 45 described above. In other embodiments, encapsulation layer 118 may comprise another stereolithography liquid substance or additives to liquid that may improve the encapsulation functionality or other attributes, such as flexibility of sample 99.

This particular process sequence of FIG. 6 is shown by way of example, in order to illustrate certain problems, such as compact packaging and interconnecting of devices having different size and/or shape and/or form factor, that are addressed by embodiments of the present invention and to demonstrate the application of these embodiments in enhancing the performance of sample 99. Embodiments of the present invention, however, are by no means limited to this specific sort of example process sequence, and the principles described herein may similarly be applied to other sorts of processes or using other process parameters between the processes described above (e.g., illumination time carried out by SLI 55). More specifically, the immersion of devices 100 and 110 in liquid 44 and using the other processes described in FIG. 6, enables the compact packaging and interconnecting of devices 100 and 110 within sample 99. Thereby allowing also heterogenous integration of components or devices having functionalities different from one another.

Note that sample 99 remains within SLV 22 of system 10 during the entire process sequence of FIG. 6. Moreover, as described above, the process sequence of FIG. 6 is simplified for the sake of conceptual clarity, and production process sequences may comprise additional processes, such as but not limited to surface preparation, melting, annealing and curing, cleaning and rinsing, metrology and inspection.

FIG. 7 is a diagram that schematically illustrates a method and process sequence for embedding multiple types of liquids in a sample 199, in accordance with an embodiment of the present invention. Sample 199 may replace, for example, sample 99 of FIG. 1 above, such that all the processes described in FIGS. 1-6 above may be carried out in the method described in FIG. 7, and applied to sample 199.

The method begins at a step 1 with a formation of a cavity 120 in sample 199 using the techniques described in steps 1 and 2 of FIG. 6 above. In some embodiments, processor 11 controls mount 33 to move along z-axis so as to immerse sample 99 in liquid 44. Subsequently, processor 11 controls mounts 30 and 33 to position sample 99 aligned with or in close proximity to SLI 55, and further controls SLI 55 to project image 20 (not shown) on predefined locations of liquid 44 and to form a pattern of solid layer 45 using the polymerization process described in step 3 of FIG. 4 above. Note that after concluding step 1, cavity 120 contains liquid 44 that was not exposed to image 20 projected by SLI 55.

Subsequently, the method comprises various techniques for evacuating liquid 44 from cavity 120. In the example of FIG. 7, the method comprises two alternative techniques, shown as two alternative branches: (a) a liquid suction branch and (b) a liquid rejection branch. In an embodiment, processor 11 may implement the liquid evacuation using one of the aforementioned alternative techniques, or any suitable combination thereof. Embodiments of the present invention, however, are by no means limited to these specific sort of example techniques and processor 11 may apply any other suitable technique for evacuating liquid 44 from cavity 120.

Reference is now made to the liquid suction branch. In some embodiments, system 10 comprises a liquid suction subsystem having a thin tube 121 coupled to a pump (not shown). In some embodiments, a distal end 123 of tube 121 has an outer diameter of about 200 μm and an inner diameter of about 100 μm, or any other suitable diameters. The pump is configured to apply an under-pressure of about 0.5 atmosphere so as to pump liquid 44, through tube 121, out of cavity 120. At a step 2, processor 11 controls mounts 30 and 33 to position a lower surface 119 of cavity 120 in close proximity to distal end 123 of tube 121. Subsequently, processor 11 controls the pump of the liquid suction subsystem to apply the aforementioned pressure to tube 121 so as to pump liquid 44 out of cavity 120.

Reference is now made to the liquid rejection branch. At a step 2A, processor 11 controls mounts 30 and 33 to position cavity 120 aligned with PP 77, and further controls PP 77 to insert a solid element 122 into cavity 120. Note that solid element 122 has dimensions similar to that of cavity 120, and therefore, in response to the insertion of solid element 122 into cavity 120, liquid 44 overflows away from cavity 120 and located on an upper surface 124 of layer 45.

At a step 2B, processor 11 controls wiper 80 to move, relative to cavity 120, in a direction represented by an arrow 126 so as to remove liquid 44 away from upper surface 124.

At a step 2C, processor 11 controls mounts 30 and 33 to position cavity 120 aligned with PP 77, and further controls PP 77 to retract solid element 122 away from cavity 120.

As described above after concluding the liquid suction branch or the liquid rejection branch, liquid 44 has been evacuated from cavity 120. In some embodiments, system 10 comprises a dispensing subsystem 130 coupled to chassis 31. At a step 3, processor 11 controls mounts 30 and 33 to position cavity 120 aligned with dispensing subsystem 130, and further controls dispensing subsystem 130 to dispense a liquid 128 that is photosensitive into cavity 120. In other embodiments, system 10 may comprise any other suitable type of subsystem (e.g., inkjet) configured to apply liquid 128 into cavity 120.

In some embodiments, photosensitive liquid 128 which may comprise a flexible and/or stretchable material after polymerization, such as but not limited to photosensitive Silicone. The flexibility of the material may be obtained by adding certain additives to liquid 44 which make it more flexible, for example adding polyols (long chain which do not cross link with the main chains and thereby make the material elastic/flexible). Alternatively the flexibility may be obtained by starting with epoxy active moieties which are linked to a flexible main chain (e.g. a silicone chain).

In such embodiments, embedded flexible materials may improve the local flexibility of sample 199 and create a combination of rigid and flexible sections of sample 199. Thus, rigid sections may comprise rigid components or devices, and flexible or stretchable sections may provide the structure of sample 199 with the specified flexibility or Stretchability for fulfilling a specified functionality of sample 199.

In other embodiments, substrate 60 may comprise flexible materials and liquid 128 may replace liquid 44 so as to produce a flexible polymeric matrix instead of the rigid polymeric matrix obtained by using liquid 44. In such embodiments, liquid 44 or any other suitable type of rigidly polymerized material may be used for obtaining specific rigid sections (e.g., for filling specific cavities and/or for having rigid devices embedded therein) within the flexible polymeric matrix described above. Moreover, in such embodiments, at least some of the electrical traces may comprise flexible conductors, or meander-based solid conductors.

In some embodiments, system 10 is configured to produce electrically conductive traces adapted for stretchable circuits. For example using LDW 66 for metal printing, or using any suitable type of dispensing subsystem described above.

In some embodiments, system 10 is configured to print electrically conductive traces using conductive pastes that maintain a degree of stretchability after a curing process. Such pastes may comprise, for example, silver-ink-based products, such as but not limited to CI-1036, produced by Engineered Materials Systems, Inc. (EMS, Inc), Delaware, Ohio.

Additionally or alternatively, system 10 is configured to print the aforementioned conductive traces in meander shapes that enable stretching of these traces, and yet, maintaining the specified resistance of the stretchable circuitry.

In some embodiments, liquids 44 and 128 comprise suitable materials that may not mix with one another, neither in liquid phase nor in liquid/solid phase. For example, liquid 128 may not diffuse into polymerized layer 45. Additionally or alternatively, liquids 44 and 128 may have different thermal or electrical properties so as to control thermal and electrical conductance and/or capacitance or any other properties at different sections of sample 199.

At a step 4, processor 11 controls mount 33 to move along z-axis so as to immerse sample 199 in liquid 44. Subsequently, processor 11 controls mounts 30 and 33 to position sample 199 aligned with or in close proximity to SLI 55, and further controls SLI 55 to project image 20 on a section 132 of liquid 44 and to form, in section 132, a pattern of solid layer 45 using the polymerization process described in step 3 of FIG. 4 above.

In some embodiments, solid layer 45 may be used for encapsulating liquid 128 within cavity 120 of sample 199. In other embodiments, system 10 is configured to produce encapsulation layer 118 (shown and described in step 10 of FIG. 6 above) instead of or in addition to layer 45. Note that sample 199 remains within SLV 22 of system 10 during the entire process sequence of FIG. 7.

In some embodiments, using multiple liquids, such as liquids 44 and 128 may affect various properties of sample 199. For example, new products, such as sensors, actuators and power sources (e.g., batteries) may be produced by locally adjusting mechanical, and/or thermal and/or electrical properties of a sample.

In other embodiments, one or more cavities of sample 199, such as cavity 120, may be filled with a solid phase change material (PCM), such as paraffin wax, which is configured to locally change properties (e.g., mechanical, thermal, or electrical) of sample 199.

In such embodiments, processor 11 may dispose the solid PCM (not shown) in sample 199 by controlling PP 77 to position a bulk of solid PCM having dimensions that can fit into the respective cavity 120, or using any other suitable implementation technique.

In other embodiments, instead of producing solid layer 45, system 10 may control PP 77 to position a solid capping component (not shown) for encapsulating liquid 128 within cavity 120 of sample 199. In yet other embodiments, system 10 may encapsulate liquid 128 within cavity 120 using any other suitable technique, for example, using a combination of the aforementioned solid capping component with solid layer 45 produce below, and/or above, and/or in the sides of the solid capping component.

### Producing Actuators and Sensors by Locally Adjusting Mechanical and Thermal Properties of a Sample

FIG. 8 is a diagram that schematically illustrates a method and process sequence for producing an actuator 200, in accordance with an embodiment of the present invention. The method begins at a step 1 with producing a heating element 201 using system 10.

In some embodiments, processor 11 controls mounts 30 and 33 to position a substrate 206 of actuator 200 aligned with or in close proximity to LDW 66. Subsequently, processor 11 controls LDW 66 to print (or deposit and pattern using any other suitable technique) a heating element 201 comprising pads 202 and a resistor 204.

Reference is now made to an inset 211 showing a top view of heating element 201 formed on substrate 206. In some embodiments, pads 202 comprise copper or any other suitable material or alloy having any suitable low electrical resistivity (e.g., resistivity smaller than about 15 μΩ·cm). Resistor 204 comprises nickel-chrome or any other suitable material or alloy having electrical resistivity larger than about 200 μΩ·cm, which is larger than that of pads 202.

In some embodiments, LDW 66 is configured to produce pads 202 and resistor 204 in a single process step. For example, the donor of LDW 66 (not shown) may comprise at least a first donor film comprising copper at a first location on the donor, and one or more second donor films, each of which comprising nickel and chrome (together or separately) and located at a second different location on the donor film.

In other embodiments, LDW 66 is configured to produce heating element 201 in two or more process steps. For example, by having copper on a first donor and nickel and chrome on a second donor and replacing the first and second donors between the process steps. In alternative embodiments, LDW 66 may produce heating element 201 using any other suitable process sequence and deposition techniques.

In some embodiments, pads 202 may be electrically coupled, e.g., via electrical traces (not shown), to a power source (not shown). During operation of actuator 200, the power source may apply a predefined voltage level to pads 202 so as to increase the temperature of heating element 201 caused by the electrical resistance of resistor 204.

Reference is now made to a step 2 of FIG. 8. In some embodiments, system 10 may apply one or more of the techniques described in FIG. 7 above for producing a cavity 208 on top of resistor 204, and for filling cavity 208 with any suitable substance, such as a liquid 210. In an embodiment, liquid 210 is configured to expand, e.g., for the purpose of actuation, in response increased temperature caused by applying the aforementioned voltage level to pads 202 of heating element 201. In another embodiment, processor 11 may apply PP 77 for positioning, instead of liquid 210, a solid member (not shown) having similar expansion properties for actuation.

In some embodiments, the substance (e.g., liquid 210 or the solid member) has a coefficient of thermal expansion (CTE) larger than the CTE of layer 45. Additionally or alternatively, the substance may have a mechanical rigidness smaller than the mechanical rigidness of layer 45. In other words, in response to a given mechanical force applied to sample 200, liquid 210 or the aforementioned solid member will be deformed, whereas layer 45 will not be deformed.

At a step 3, processor 11 controls mounts 30 and 33 to position cavity 208 aligned with PP 77, and further controls PP 77 to place a flexible membrane 212 on top of liquid 210. In some embodiments, flexible membrane 212 may comprise polyimide or silicone or any other suitable material or any suitable combination thereof. In other embodiments, system 10 is configured to deposit flexible membrane 212 using any suitable technique. Note that flexible member 212 may have a mechanical flexibility larger than the mechanical flexibility of layer 45.

At a step 4, processor 11 controls mounts 30 and 33 to immerse device 100 in liquid 44 and to position cavity 208 aligned with or in close proximity to SLI 55. Subsequently, processor 11 controls SLI 55 to project image to predefined locations of liquid 44 and form solid layer 45 by the polymerization process described in step 3 of FIG. 4 above. Note that after concluding step 4, flexible member 212 is fixated by layer 45. In an embodiment, a surface 215 of liquid 44 and a surface 214 of layer 45 are flush with one another, and a surface 216 of liquid 212 is located below surface 214.

In some embodiments, step 4 terminates the production process of actuator 200 and the remaining of liquid 44 are removed using any suitable technique, such as liquid suction or liquid rejection described in FIG. 7 above, or simply washed away by rinsing actuator 200.

Reference is now made to a step 5, which is an operational step carried out after concluding the production of actuator 200. In some embodiments, before applying the voltage to pads 204, surface 214 of actuator 200 is coupled to a surface of an external device or product (not shown).

In some embodiments, at step 5, the aforementioned power supply applies the predefined voltage level to pads 202 so as to increase the temperature of resistor 204 of heating element 201 as described in step 1 above. In response to the increased temperature, the volume of liquid 210 increases, such that at least flexible membrane 212, and optionally a portion of liquid 210, protrude from cavity 208 and exceed surface 214, so as to function as a thermal-driven actuator.

In other embodiments, in response to the increase in temperature described above, at least some of liquid transitions phase from liquid to gas, which further expands and increases the actuation force applied by flexible member 212.

In other embodiments, the techniques described above may be used for producing other products, such as various types of sensors. For example, a strain gauge (not shown) may be formed by producing, in lieu of resistor 204, a capacitor (not shown) having two electrodes laid out in parallel to surface 214, at a predefined distance from one another, wherein each of the electrodes is electrically coupled to a different pad 202. The sensor may additionally have surface 216 of flexible member 212 flush with surface 214 of layer 45. Subsequently, the sensor is coupled, e.g., via surface 214, to an external device or product intended to apply a mechanical force to flexible member 212.

In yet other embodiments, system 10 is configured to produce any other suitable type of passive elements, such as but not limited to vertical inductor coils and printed vertical coils with ferrite core.

In such embodiments, when the mechanical force is applied to the sensor, flexible member 212 is pushed by the mechanical force toward liquid 210. In response, liquid 210 moves the closest electrode so that the distance between the electrodes is reduced and changes the capacitance of the capacitor, which is measured using any suitable technique. Processor 11 may estimate, based on the change in capacitance, the amount of mechanical force applied, by the external entity, to flexible member 212.

In the process sequences described in FIGS. 1-8 above, liquids 44, 128 and 210 make contact with solid surfaces having various types of materials (e.g., metal, ceramics, polymers), various degrees of roughness and other properties that may affect the wetting between any of liquids 44, 128 and 210 and a respective solid surface. The wetting effect may cause undesired phenomena, for example, insufficient adhesion between liquid 44 and a solid surface, insufficient coverage of 3D geometries by liquid 44, and possibly by layer 45 after the polymerization process.

The inventors found that the wetting effect may be controlled by controlling the viscosity of the respective liquid. In some embodiments, processor 11 may control mount to position the processed sample aligned with the aforementioned IR laser-based melting/annealing/curing heating subsystem, and subsequently, may control the melting/annealing/curing heating subsystem to irradiate the liquid (e.g., liquid 44) by IR so as to instantly heat the liquid, and thereby, to reduce the viscosity thereof. The reduced viscosity improves the wetting of the respective solid surface by liquid 44. Subsequently, processor 11 may control mounts 30 and 33 to position sample 99 in close proximity to SLI 55 and further controls SLI 55 to polymerize liquid 44 so as to retain the improved wetting of the respective solid surface by solidifying liquid 44.

In other embodiments, one or more cavities 208 of sample 200, may be filled with a solid phase change material (PCM) instead of or in addition to liquid 210. As described in FIG. 7 above, the PCM is configured to locally change mechanical and/or thermal and/electrical or other properties of sample 200.

Note that sample 200 remains within SLV 22 of system 10 during the entire process sequence of FIG. 8.

### Vertical Stacking of Electronic Devices in a Polymeric Matrix

FIG. 9 is a diagram that schematically illustrates a method and process sequence for packaging multiple devices in a polymeric matrix, in accordance with another embodiment of the present invention. The process sequence of FIG. 9 comprises process steps and techniques similar to that described in detail in FIG. 5 above, and therefore will be briefly described herein. Yet, the structure of a sample 250 of FIG. 9 differs from that of sample 99 of FIG. 5 above. The structural differences between samples 99 and 250 will be described in detail herein.

The method begins at a step 1 with (a) immersing sample 250 in a liquid 246 having a thickness smaller than the height of device 240, (b) using PP 77 for placing device 240 at a predefined position on a surface 273 of a substrate 260, (c) forming a polymeric matrix, in the present example, a layer 263, by polymerizing liquid 246 at selected locations of sample 250, in the present example the polymeric matrix is surrounding device 240 for fixating the position of device 240, (d) using LDW 66 for producing pillars 270, (e) immersing sample 250 in liquid 246 having a thickness larger than the height of pillars 270, using a wiping process for reducing the thickness of liquid 246, as described for example in step 2 of FIG. 3 above, and/or in step 3 of FIG. 5 above, and polymerizing liquid 246 at selected locations of sample 250. The polymerization of liquid 246 may be carried out at least in locations surrounding pillars 270 for fixation the position thereof. Note that sub-steps (a)-(e) are similar to steps 1-4 of FIG. 5 above.

At a sub-step (f), processor 11 controls mounts 30 and to position pillars 270 aligned with or in close proximity to LDW 66 and further controls LDW 66 to reveal the top surface of pillars 270 (as described, for example, in step 4 of FIG. 3 above), and thereafter, to print electrical traces 272, which are electrically connected to pillars 270. Subsequently, the method comprises forming layer 263 in closed proximity to electrical traces 272, for fixating the position thereof, using the immersion and polymerization processes of liquid 246 as described in sub-step (e) above.

At a sub-step (g) that concludes step 1, processor 11 controls mounts 30 and 33 to position sample 250 aligned with or in close proximity to LDW 66, and further controls LDW 66 to print pillars 274, which are electrically connected to electrical traces 272.

At a step 2, the method comprises forming a cavity 280 using the techniques described above. For example, the technique described in step 3 of FIG. 3, and/or the technique described in step 1 of FIG. 7. Note that at step 2 the method further comprises the fixation of pillars 274 in layer 263.

At a step 3, processor 11 controls PP 77 to position device 242 within cavity 280 and further controls wiper 80 for wiping liquid 246 rejected from cavity 280 due to the insertion of device 242. Subsequently, processor 11 controls LDW 66 for printing electrical traces 276 having an electrical contact with pads (not shown) of device 242, and for printing pillars 278 having an electrical contact with electrical traces 276. Note that the printing of electrical traces 276 and pillars 278 may be carried out by LDW 66 in a single process step or multiple process steps.

At a step 4 that concludes the method of FIG. 9, the method comprises (a) formation of a cavity 282 using the techniques of step 2 above, (b) placing device 244 in cavity 282 and producing electrical traces 284 having an electrical contact with pads (not shown) of device 244, as described in step 3 above, and (c) encapsulating sample 250 using any suitable technique, such as the technique described in step 10 of FIG. 6 above.

In some embodiments, the duration of any of the processes described above may be dictated by various parameters, such as but not limited to the polymerization rate of liquid 44, the deposition rate of a given layer by LDW 66, and the operational sequence (e.g., the more moves of sample 99 between stations, the longer duration of the respective process).

In some embodiments, the polymerization rate of liquid 44 may be affected by: (a) the chemical composition (e.g., rheological properties) and temperature of liquid 44, (b) the illumination intensity and wavelength carried out by SLI 55, (c) the precision control of the thickness of liquid 44, and any combination thereof.

In some embodiments, based on (a) the design of the end-product of sample 99, e.g., the thickness of the devices placed by PP 77, the thickness of layers, and thermal budget of the process (to prevent damage to components and/or the specified chemical composition and mechanical structure), and (b) the process limitations described above, processor 11 is configured to select a sequence of process steps that optimizes between tradeoffs of the product quality and the total duration of the manufacturing process of the end-product.

Additionally or alternatively, system 10 is configured to improve the average production cycle time of each product by processing multiple samples 99 in parallel. For example: (a) system may comprise multiple subsystems of the long and/or mostly used processes (e.g., two sets of SLV 22 and SLI 55 subsystems) coupled to chassis 31 instead of or in addition to subsystem 88, and (b) processor 11 may process different samples at different subsystems at the same time, subject to specified queue times between steps of the process sequence.

Note that sample 250 remains within SLV 22 of system 10 during the entire process sequence of FIG. 9.

In some embodiments, at least one of devices 240, 242 and 244 may be flipped, using any suitable process of flip-chip techniques. For example, device 244 may have the active area facing substrate 260, referred to herein as “facing down.”

In other embodiments, at least one of devices 240A and 240B may comprise pads facing down (i.e., facing substrate 260). For example, the active area of device 240A may be facing trace 284, and the non-active surface of device 240A may be facing substrate 260. In this configuration, the non-active surface of device 240A may comprise electrically-conductive contact pads. In these embodiments, processor 11 is configured to control a dispenser, which is mounted on chassis 31, to apply electrically conductive adhesive (e.g. epoxy or silicone filled with metal), or solder, or any other suitable type of electrically conductive substance or alloy, to the contact pads. Subsequently, system 10 is configured to carry out a curing process step, so as to harden the conductive adhesive and to improve the adhesion the electrical conductivity between the conductive adhesive and contact pad.

In some embodiments, the curing step may be carried out immediately after applying the conductive adhesive by locally heating device 240. For example, using a photonic curing process, as described, for example, by Abbel et al., in “Roll-to-Roll Fabrication of Solution Processed Electronics,” ADV. ENG. MATER. 2018, 1701190, DOI: 10.1002/ADEM.201701190, which is incorporated herein by reference. Such photonic curing products are provided, for example, by Novacentrix (400 Parker Dr., Suite 1110, Austin Tex.).

In other embodiments, if the conductive adhesive is compatible with liquid 246 or with any other suitable type of stereolithography resin, system 10 is configured to carry out the adhesive curing process step using a thermal process after completing the buildup of the product of sample 250.

In other embodiments, system 10 is configured to remove liquid 246 or a section of layer 263 so as to enable applying the conductive adhesive or solder on the contact pad, and subsequently, to carry out the curing process step described above.

Although the embodiments described herein mainly address production of 3D electronic and optoelectronic devices, allow various forms of advanced electronic packaging as well as producing various types of sensors and actuators, the methods and systems described herein can also be used in other applications, such as in bodily wearable functional devices for e.g. medical or entertainment, other compact and complex shape medical devices, such as hearing aids, or internet of things (IOT) devices with sensing and communication capabilities.

It will thus be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. A method for manufacturing, the method comprising:
coupling a sample to a mount, and immersing at least part of the sample in a photosensitive liquid having an upper surface defining an interface between the photosensitive liquid and a surrounding environment; and
forming at least a polymer layer coupled to at least a section of the sample, by:
setting a thickness of the polymer layer by controlling a position of the sample relative to the upper surface; and
illuminating at least the upper surface so as to polymerize the photosensitive liquid to form the polymer layer.

2. The method according to claim 1, wherein illuminating at least the upper surface comprises using two or more wavelengths or two or more ranges of wavelengths.

3-5. (canceled)

6. The method according to claim 1, comprising directing droplets of molten material toward at least a solid surface of the sample in accordance with a predefined pattern so that the droplets harden on the solid surface to print a structure of one or more layers on the solid surface.

7. The method according to claim 6, wherein the solid surface comprises at least part of the polymer layer and wherein the method further comprises:
removing at least part of the polymer layer for exposing at least a given surface of the structure to the surrounding environment; and
forming an electrical contact on the given surface by directing additional droplets toward a predefined position on the given surface in accordance with an additional predefined pattern so that the additional droplets harden on the given surface to print the electrical contact at the predefined position.

8-23. (canceled)

24. The method according to claim 1, further comprising (a) forming an electrical component above or below the polymer layer, (b) patterning a cavity in the polymer layer, (c) filling the cavity with a substance that differs from the polymer layer, and (d) disposing a flexible member at least on the substance, wherein the electrical component comprises a resistor, and wherein the substance has a first coefficient of thermal expansion (CTE) larger than a second CTE of the polymer layer.

25-27. (canceled)

28. The method according to claim 1, wherein the photosensitive liquid comprises one or more substances selected from a list consisting of: (a) chemical moieties photopolymerizable to form epoxy or silicone polymers, (b) polyimides, (c) polyurethanes, (d) polydicyclopentadienes, (e) photosensitive polymerizable silanes, and (f) photopolymerizable moieties.

29-36. (canceled)

37. The method according to claim 1, comprising forming a first three-dimensional (3D) structure by directing first droplets of molten material toward at least a solid surface of the sample in accordance with a predefined pattern so that the first droplets harden on the solid surface to print the first 3D structure on the solid surface, wherein the first 3D structure comprises a first end having a lower surface facing the solid surface and a second end having an upper surface opposite to the lower surface, and comprising forming, on the upper surface, a second 3D structure by directing second droplets of molten material toward the upper surface, so that the second droplets harden on the upper surface to print the second 3D structure on the upper surface of the first 3D structure, wherein forming at least the polymer layer comprises: (i) forming a first polymer layer for fixating a position of the first 3D structure on the solid surface, and (ii) forming a second polymer layer for fixating the position of the second 3D structure on the upper surface of the first 3D structure.

38-40. (canceled)

41. A system for manufacturing, the system comprising:
a vat configured to contain a photosensitive liquid having an upper surface defining an interface between the photosensitive liquid and a surrounding environment;
a mount, having a sample coupled thereto and configured to immerse at least part of the sample in the photosensitive liquid by moving the sample relative to the upper surface;
an optical assembly, which is configured to illuminate at least the upper surface so as to polymerize the photosensitive liquid to form a polymer layer; and
a processor, which is configured to set a thickness of the polymer layer by controlling a position of the sample relative to the upper surface.

42-67. (canceled)

68. The system according to claim 41, wherein the photosensitive liquid comprises one or more substances selected from a list consisting of: (a) chemical moieties photopolymerizable to form epoxy or silicone polymers, (b) polyimides, (c) polyurethanes, (d) polydicyclopentadienes, (e) photosensitive polymerizable silanes, and (f) photopolymerizable moieties.

69. The system according to claim 41, wherein the optical assembly is configured to illuminate using ultraviolet (UV) radiation.

70. The system according to claim 41, and comprising a laser direct writing subsystem (LDW), and wherein the processor is configured to control the LDW to prepare a given surface of the polymer layer before applying a layer or coupling a device to the given surface.

71. The system according to claim 70, wherein the processor is configured to control the LDW to direct droplets of molten material toward the given surface of the polymer layer in accordance with a predefined pattern so that the droplets harden on the given surface to print the layer on the given surface.

72-76. (canceled)

77. The system according to claim 41, and comprising a laser direct write subsystem (LDW), which is configured to form a first three-dimensional (3D) structure by directing first droplets of molten material toward at least a solid surface of the sample in accordance with a predefined pattern so that the first droplets harden on the solid surface to print the first 3D structure on the solid surface, wherein the first 3D structure comprises a first end having a lower surface facing the solid surface and a second end having an upper surface opposite to the lower surface, wherein the LDW is configured to form, on the upper surface, a second 3D structure by directing second droplets of molten material toward the upper surface, so that the second droplets harden on the upper surface to print the second 3D structure on the upper surface of the first 3D structure, and wherein the processor is configured to control the mount and the optical assembly so as to: (i) form a first polymer layer for fixating a position of the first 3D structure on the solid surface, and (ii) form a second polymer layer for fixating the position of the second 3D structure on the upper surface of the first 3D structure.

78-80. (canceled)

81. A method for manufacturing, the method comprising:
ejecting droplets of molten material toward a substrate in a predefined pattern so that the droplets harden on the substrate to print a three-dimensional (3D) structure on the substrate;
immersing the substrate, with the 3D structure thereon, into a photosensitive liquid; and
irradiating the photosensitive liquid so as to polymerize the photosensitive liquid to form one or more polymer layers that contain at least part of the 3D structure.

82. The method according to claim 81, wherein the droplets comprise a molten metal.

83. The method according to claim 82, further comprising placing an electronic device on the substrate, wherein ejecting the droplets comprises making a conductive connection to the electronic device.

84. The method according to claim 83, wherein making the conductive connection comprises printing a pillar, which extends through one or more of the polymer layers formed by polymerizing the photosensitive liquid.

85. The method according to claim 82, wherein ejecting the droplets comprises directing a laser beam to impinge on a donor film so that the droplets are ejected by laser-induced forward transfer (LIFT).

86. The method according to claim 82, wherein irradiating the photosensitive liquid comprises applying patterned radiation to the photosensitive liquid so as to build up multiple polymer layers in a process of stereolithography.

87. The method according to claim 86, wherein ejecting the droplets comprises printing the 3D structure on a first stereolithographic layer, which serves as the substrate for the 3D structure, and wherein applying the patterned radiation comprises forming at least a second stereolithographic layer over the first stereolithographic layer.
